(19) United States
(12) Patent Application Publication
(10) Pub. No.: US 2013/0000697 A1
(43) Pub. Date: Jan. 3, 2013

(54) SOLAR CELL MODULE AND SOLAR PHOTOVOLTAIC DEVICE

(75) Inventors: Tsuyoshi Maeda, Osaka (JP); Hideki Uchida, Osaka (JP)

(73) Assignee: Sharp Kabushiki Kaisha, Osaka (JP)

(21) Appl. No.: 13/634,791

(22) PCT Filed: Mar. 2, 2011
(86) PCT No.: PCT/JP2011/054792

§ 371 Date: Sep. 13, 2012

(30) Foreign Application Priority Data
Mar. 30, 2010 (JP) 2010-079579

(51) Int. Cl. H01L 31/052

(52) U.S. Cl. 136/246

(57) ABSTRACT

A solar cell module (10) of the present invention includes a light guide plate (1), a solar cell element (2) and a light diffusion section (3). The light diffusion section (3) is provided on a light-incident surface of the light guide plate (1), which light-incident surface receives sunlight. Further, the solar cell element (2) is provided on an intersecting surface (end surface) which intersects the light-incident surface of the light guide plate (1). The light diffusion section (3) is provided so that the farther away from the solar cell element (2) a position is, the larger an amount of light diffused by the light diffusion section (3) is. The light diffusion section (3) diffuses light entering the light guide plate (1), so as to enhance efficiency of gathering light to the solar cell element (2).

### TECHNICAL FIELD

The present invention relates to a solar cell module and a solar power generating device including the solar cell module.

### BACKGROUND ART

In order to utilize solar energy efficiently, a conventional solar power generating device is generally used while being arranged such that a plurality of solar panels are provided on a single plane without any gap between them, and face toward the sun. Since each of the plurality of solar panels is generally constituted by opaque semiconductors, it is impossible to have an arrangement in which the plurality of solar panels to be laminated with each other. Therefore, in order to gather sunlight sufficiently, it is necessary to use a large-area solar panel. Further, with such a large-area solar panel, there is an increase in area necessary for provision of the solar power generation device is provided.

As a technique of efficiently utilizing solar energy while realizing a reduction in an area of the solar panel, Patent Literature 1 describes such a technique that (i) a solar cell is attached to a side surface of a light-absorption/light-emitting plate, which side surface is perpendicular to a light-incident surface of the light-absorption/light-emitting plate in which a fluorescent material is dispersed, and (ii) the light-absorption/light-emitting plate is provided as a surface of a window of a building. With the technique, sunlight entering the light-incident surface is guided through the light-absorption/light-emitting plate, so as to be gathered to the solar cell.

Further, Patent Literatures 2 through 4 describe a technique of improving power generation efficiency of a solar panel by gathering sunlight to a solar cell efficiently. In order to gather sunlight to the solar cell efficiently, a light-gathering device described in Patent Literature 2 has an arrangement in which (i) a solar cell is provided on an end surface of a light guide plate having a wedge shape, and (ii) the light guide plate is such that a surface which is opposite to a surface on which sunlight is incident serves as a light scattering/reflecting surface. Furthermore, a solar cell module described in Patent Literature 3 has an arrangement in which (i) concavities and convexities are formed on a surface of a light guide plate, which surface receives sunlight, and (ii) a solar cell is provided on a back plane of the surface. With the arrangement, efficiency of gathering light to the solar cell is increased. Further, a sunlight-gathering device described in Patent Literature 4 has an arrangement in which an anisotropic scattering layer is provided on a surface of a light guide plate having a wedge shape, which surface receives sunlight, and a solar cell is provided on an end surface of the light guide plate. With the arrangement, the efficiency of gathering light to the solar cell is improved.

### CITATION LIST

### Patent Literatures

Patent Literature 1
Japanese Utility Model Application Publication, Jitsukaisho, No. 61-136559 U (1986) (Publication Date: Aug. 25, 1986)
Patent Literature 2
Japanese Patent Application Publication, Tokukaihei, No. 7-122771 A (1995) (Publication Date: May 12, 1995)
Patent Literature 3
Japanese Patent Application Publication, Tokukai, No. 2006-107861 A (Publication Date: Apr. 20, 2006)
Patent Literature 4
Japanese Patent Application Publication, Tokukai, No. 2007-218540 A (Publication Date: Aug. 30, 2007)

### SUMMARY OF INVENTION

### Technical Problem

With the technique described in Patent Literature 1, it is unnecessary to cause the solar panel to have a large area to gather sunlight. However, since the substrate in which a large amount of a fluorescent material is mixed is used, a manufacturing cost is increased. Further, if the light incident on the panel is repeatedly subjected to total reflection in the light-absorption/light-emitting plate, the light-gathering efficiency is decreased. This is because the light becomes in contact with the fluorescent material repeatedly. Furthermore, since the fluorescent material is dispersed in the substrate, coloring of the substrate occurs.

Moreover, with the techniques described in Patent Literatures 2 and 4, the light guide plate has a wedge shape. This makes it difficult to attach the solar panel to an existing window frame to use the solar panel as a windowpane. Particularly, with the technique described in Patent Literature 2, the surface opposite to the surface on which sunlight is incident serves as a reflecting surface. That is, the light guide is not transparent, and therefore the solar panel cannot be suitably used as a windowpane. Further, the light is gathered to an end part by use of the light guide plate having a wedge shape. For this reason, the larger the area of the solar panel becomes, the less the light-gathering efficiency becomes significantly. That is, according to the technique described in Patent Literature 2, it is difficult to make a large solar panel. Furthermore, with the technique described in Patent Literature 3, since the solar cell is provided on the back plane of the surface on which sunlight is incident, the light guide plate can not transmit sunlight. It is therefore impossible to attach the solar panel of Patent Literature 3 to an existing window frame to use the solar panel as a windowpane.

For the reasons described above, there has been demand for development of a solar cell module which (i) realizes a reduction in space necessary for the solar cell module, (ii) has high flexibility in its design, and (iii) has high light-gathering efficiency.

The present invention is made in view of the problems. An object of the present invention is to provide a solar cell module which has high flexibility in its design and high light-gathering efficiency, and a solar power generating device including the solar cell module.

### Solution to Problem

In order to attain the object, a solar cell module of the present invention includes: at least one light guide plate; a light diffusion section which is provided on at least one of a light-incident surface of the at least one light guide plate and a back surface of the at least one light guide plate, which back surface is opposite to the light-incident surface, the light diffusion section diffusing light entering the at least one light guide plate; and a solar cell element being provided on one of a plurality of intersecting surfaces that intersect the at least one of the light-incident surface and the back surface, on which the light diffusion section is provided, the light diffusion section being provided so that the farther away from the solar cell element a position is, the larger an amount of light diffused by the light diffusing section in the position is. Further, in order to attain the object, a solar power generating device of the present invention includes the solar cell module described above.

According to the above arrangement, the light diffusion section is provided so that the farther away from the solar cell element a position is, the larger an amount of light diffused by the light diffusing section in the position is. Accordingly, it is possible to (i) diffuse a large amount of light in a position away from the solar cell element, and (ii) suppress diffusion of light in a position close to the solar cell element to reduce loss of light thus guided (light traveling to the outside via upper and lower surfaces). This enhances efficiency of gathering light to the solar cell element. Moreover, the solar cell element is provided on the surface which intersects the light-incident surface of the light guide plate. It is therefore possible to provide a solar cell module which (i) has a small area, (ii) has sufficient power generation efficiency, and (iii) can be manufactured at a low cost. For this reason, the solar cell module can constitute a highly-efficient solar power generating system in such a manner that the solar cell module is attached to a window frame of a building or a vehicle, and used there, or is attached to a roof of a building and used there. In other words, it is possible to provide a solar cell module which has high flexibility in its design and has high light gathering efficiency. Further, a solar power generating device including such a solar cell module can have the same effects of those of the solar cell module.

Additional objects, features, and strengths of the present invention will be made clear by the description below. Further, the advantages of the present invention will be evident from the following explanation in reference to the drawings.

### Advantageous Effects of Invention

A solar cell module of the present invention includes: at least one light guide plate; a light diffusion section which is provided on at least one of a light-incident surface of the at least one light guide plate and a back surface of the at least one light guide plate, which back surface is opposite to the light-incident surface, the light diffusion section diffusing light entering the at least one light guide plate; and a solar cell element being provided on one of a plurality of intersecting surfaces that intersect the at least one of the light-incident surface and the back surface, on which the light diffusion section is provided, the light diffusion section being provided so that the farther away from the solar cell element a position is, the larger an amount of light diffused by the light diffusion section in the position is. Accordingly, it is possible to provide a solar cell module which has high flexibility in its design and has high light gathering efficiency.

### BRIEF DESCRIPTION OF DRAWINGS

FIG. 1

FIG. 1 is a perspective view illustrating a solar cell module in accordance with one embodiment of the present invention.

FIG. 2

FIG. 2 is a perspective view illustrating a solar cell module in accordance with another embodiment of the present invention.

FIG. 3

FIG. 3 is a cross-sectional view illustrating a solar cell module in accordance with another embodiment of the present invention.

FIG. 4

FIG. 4 is a cross-sectional view illustrating a solar cell module in accordance with another embodiment of the present invention.

FIG. 5

FIG. 5 is a cross-sectional view illustrating a solar cell module in accordance with another embodiment of the present invention.

FIG. 6

FIG. 6 is a cross-sectional view illustrating a solar cell module in accordance with another embodiment of the present invention.

FIG. 7

FIG. 7 is a cross-sectional view illustrating a solar cell module in accordance with another embodiment of the present invention.

FIG. 8

FIG. 8 is a cross-sectional view illustrating a solar cell module in accordance with another embodiment of the present invention.

FIG. 9

FIG. 9 is a perspective view illustrating a solar cell module in accordance with another embodiment of the present invention.

### DESCRIPTION OF EMBODIMENTS

### Embodiment 1

(Solar Cell Module 10)

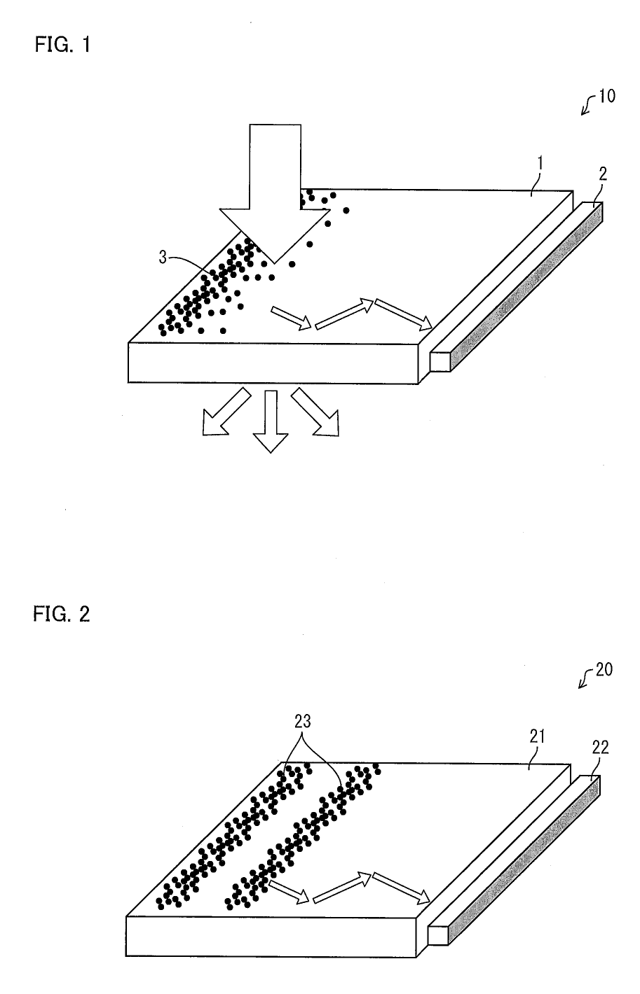

One embodiment of a solar cell module of the present invention is described below with reference to FIGS. 1 and 2. FIG. 1 is a perspective view illustrating a solar cell module 10, and FIG. 2 is a perspective view illustrating a solar cell module 20. Note that each of arrows illustrated in FIGS. 1 and 2 shows a direction in which light is incident or a direction in which light is guided.

As illustrated in FIG. 1, the solar cell module 10 includes a light guide plate 1, a solar cell element 2, and a light diffusion section 3. The light diffusion section 3 is provided on a light-incident surface of the light guide plate 1, which light-incident surface receives sunlight. Further, the solar cell element 2 is provided on an intersecting surface (end surface) of the light guide plate 1, which intersecting surface intersects the light-incident surface. In the present embodiment, the solar cell element 2 is provided on only one of four end surfaces of the light guide plate 1. Note, however, that it is possible to provide a plurality of the solar cell elements 2 on the four end surfaces of the light guide plate 1, respectively.

The light guide plate 1 only has to be a light guide plate which diffuses light entering the light-incident surface and gathers the light toward the solar cell element 2 provided on the one of end surfaces. A publicly-known conventional light guide plate can be used as the light guide plate 1. For example, the light guide plate 1 may be, but not limited to, an acrylic substrate, a glass substrate or a polycarbonate substrate. Further, a thickness of the light guide plate 1 is not particularly limited. Note, however, that it is preferable that the light guide plate 1 has a thickness of not less than a wavelength of visible light, that is, a thickness of not less than 1 μm. In view of a weight of the light guide plate 1 and an area of the solar cell arranged on the one of end surfaces, it is preferable that the light guide plate 1 has a thickness of not more than 10 cm.

The light guide plate 1 guides light incident on the light guide plate 1 to travel inside the light guide plate 1. It is preferable that the light guide plate 1 is a transparent plate which does not include a fluorescent material. However, the light guide plate 1 is not limited to this, as long as the light guide plate 1 is manufactured such that, in a manufacturing process, a dispersion process for dispersing a fluorescent material for the purpose of wavelength conversion in the light guide plate 1 is not carried out. That is, it is possible to employ suitably even a light guide plate 1 which (i) contains a fluorescent material partially without any intention of wavelength conversion and (ii) is not completely transparent.

In a case where the solar cell module 10 is installed to a window frame of a building and is used, the light guide plate 1 is constituted by an acrylic substrate or the like which has such a size and thickness that the acrylic substrate can be attached to the window frame and serve as a surface of the window. Further, in another case where the solar cell module 10 is installed on a roof and is used, a size and thickness of the light guide plate 1 may be determined appropriately in accordance with conditions such as an installation area.

As the solar cell element 2, a publicly-known solar cell can be used. For example, the solar cell element 2 may be, but not limited to, an amorphous silicon (a-Si) solar cell, a polycrystal silicon solar cell, or a monocrystal silicon solar cell. The solar cell element 2 is attached to, by use of a publicly-known conventional transparent adhesive or a publicly-known conventional transparent fastener, the surface intersecting the light-incident surface of the light guide plate 1. A size of the solar cell element 2 is not particularly limited. However, it is preferable that a width of a light receiving section of the solar cell element 2 is identical with a thickness of the light guide plate 1. This makes it possible for the light receiving section to efficiently receive light that is guided in the light guide plate 1 and reaches a side surface of the light guide plate 1.

The light diffusion section 3 diffuses light entering the light guide plate 1 and efficiently causes the light to gather to the solar cell element 2. The light diffusion section 3 is provided so that the farther away from the solar cell element 2 a position is, the larger an amount of light diffused in the position is. With the arrangement, it is possible to enhance efficiency of gathering light to the solar cell element 2 in such a manner that (i) in position far away from the solar cell element 2, a large amount of light is diffused, and (ii) in a position close to the solar cell element 2, diffusion of light is suppressed so as to reduce an amount of light traveling to an outside via upper and lower surfaces.

The light diffusion section 3 may be provided either only on the light-incident surface of the light guide plate 1, or only on a surface (back surface) opposite to the light-incident surface. Alternatively, it is possible to provide the light diffusion sections 3 on both the light-incident surface and the back surface, respectively. It is preferable to provide the light diffusion sections 3 on both the light-incident surface and the back surface, respectively. With such an arrangement, conversion efficiency of sunlight is further improved. Further, in a case where (i) the light diffusion section 3 is provided only on the back surface of the light guide plate 1, and (ii) the light guide plate 1 is used as a surface of a window so that the back surface faces an inside of the building, the light diffusion section 3 is not exposed to an outside. That is, with the arrangement, it is possible to prevent the light diffusion section 3 from being covered and filled with dirt. It is therefore possible to prevent a reduction in efficiency of gathering light to the solar cell element 2.

In the present embodiment, the light diffusion section 3 is constituted by concavities and convexities formed on a surface of the light guide plate 1. With the arrangement in which the light diffusion section 3 constituted by the concavities and convexities is formed on the surface of the light guide plate 1, the light entering the concavities and convexities from the inside of the light guide plate 1, among the light which is incident on the light guide plate 1 and then is guided inside the light guide plate 1, is diffused by the concavities and convexities, and then is returned into the light guide plate 1, after that, is guided inside the light guide plate 1. Accordingly, an amount of light which is guided inside the light guide plate 1 is increased, and an amount of light gathered to the solar cell element 2 is also increased, as compared with an arrangement having no concavities and no convexities. It is therefore possible to enhance efficiency of gathering light to the solar cell element 2.

In the light guide plate 1, the concavities and convexities are provided so that the farther away from a solar cell element 2 side a position is, the larger the number of concavities and convexities in the position is. Accordingly, a density of the concavities and convexities is high in a position away from the solar cell element 2 side, and is low in a position close to the solar cell element 2 side. Therefore, (i) the longer a distance between a position in the light guide plate 1 and the solar cell element 2 becomes, the larger an amount of light diffused in the position becomes, and (ii) the shorter the distance between a position in the light guide plate 1 and the solar cell element 2 becomes, the less an amount of light diffused in the position becomes, that is, it is possible to reduce loss (light emitted via the upper and lower surfaces) of light thus guided. With the arrangement, it is possible to enhance efficiency of gathering light to the solar cell element 2.

As illustrated in FIG. 1, it is possible to arrange the concavities and convexities, serving as the light diffusion section 3, so that the number of the concavities and convexities is gradually reduced from a position away from the solar cell element 2 toward the solar cell element 2 side in a gradation manner. Further, like the solar cell module 20 illustrated in FIG. 2, it is possible to arrange the concavities and convexities, serving as a light diffusion section 23, to form a certain pattern, as long as the concavities and convexities are densely provided as being away from a solar cell element 22 in a light guide plate 21. As illustrated in FIG. 2, by providing the concavities and convexities to form a certain pattern, it is possible to (i) obtain an effect similar to that of the solar cell module 10 illustrated in FIG. 1, and (ii) provide the solar cell module 20 which is rich in design.

As described above, the light diffusion section 3 is constituted by the concavities and convexities formed on the surface of the light guide plate 1. For this reason, the solar cell module 10 can be used as a ground glass window, in a case where the solar cell module 10 is installed to a window frame of a building and the light guide plate 1 is used as a surface of a window. A method for forming the concavities and convexities on the surface of the light guide plate 1 may be a publicly-known conventional method. Examples of such a method encompass a method for forming the concavities and convexities by spraying an abrasive by a sandblasting method, a method for forming the concavities and convexities by spraying a plurality of light diffusing members (such as silicon oxide) by a spraying method, etching treatment by use of hydrofluoric acid or the like, and a sol-gel method. The plurality of light diffusing members, used to form the concavities and convexities, may be, but not limited to, silicon oxide beads, titanium oxide beads, or alumina beads.

Next, the following description deals with how sunlight incident on the solar cell module 10 is guided in the light guide plate 1. When light enters a region having a low refractive index from a region having a high refractive index, a total reflection phenomenon may occur depending on an angle at which the light enters the region having a low refractive index. For example, in the light guide plate (acrylic substrate) 1 having a refractive index of 1.5, light incident on the light-incident surface at an angle in a range of 0° to about 41° (an angle of a normal line is 0°) travels to the outside of the light guide plate 1. On the other hand, light incident on the light-incident surface at an angle of not less than about 41° is guided in the light guide plate 1 as being subjected to total reflection repeatedly. Even in a case where an acrylic substrate having a refraction index of 1.5 is employed as the light guide plate 1, a percentage of the light which is guided in the light guide plate 1 with respect to the light which travels to the outside of the light guide plate 1 is approximately 75%.

Here, a solar cell module 10 illustrated in FIG. 1 was manufactured and power generation efficiency of the solar cell module 10 was found. First, a glass substrate (1 m×1 m) having a thickness of 3 mm was prepared, and concavities and convexities were formed by the sandblasting method on upper and lower surfaces opposite to each other. An in-plane average pitch of the concavities and convexities thus formed was 100 μm and an average roughness Ra of the concavities and convexities was 50 μm. A solar cell element 2 including a light receiving section having a width of 10 mm was provided on one of four end surfaces of the glass substrate. The concavities and convexities were provided in a gradation manner so that the number of concavities and convexities formed on upper and lower surfaces of the glass substrate (i) was significantly small in a position close to the solar cell element 2, and (ii) was large in a position farther away from the solar cell element 2. Further, a PET sheet on which Al was vapor-deposited was provided on each of the other three end surfaces, on which no solar cell element 2 was provided, so as to prevent leakage of light from the other three end surfaces. An amount of electricity generated by the solar cell module 10 thus manufactured was measured while the solar cell module 10 was irradiated with sunlight. The amount of electricity thus measured was approximately 1000 mW.

As mentioned above, according to the solar cell modules 10 and 20, the light diffusion section 3 is provided on the surface of the light guide plate 1 so that the farther away from the solar cell element 2 a position is, the larger an amount of light diffused by the light diffusion section 3 is. It is therefore possible to (i) diffuse efficiently light incident on the light guide plate 1 so as to guide the light efficiently to the solar cell element 2, and, as a result, (ii) gather the light to the solar cell element 2 efficiently. Accordingly, it is possible to enhance efficiency of gathering light to the solar cell element 2. Further, since the solar cell element 2 is provided on the surface intersecting the light-incident surface of the light guide plate 1, it is possible to provide a solar cell module which (i) has a small area, (ii) has sufficient power generating efficiency, and (iii) can be manufactured at a low cost. Furthermore, by providing the light diffusion section 3 constituted by concavities and convexities formed on the surface of the light guide plate 1, it becomes possible to provide the solar cell modules 10 and 20 each of which can be used as ground glass. Moreover, it is possible to arrange the concavities and convexities to form a certain pattern. This makes it possible to provide the solar cell modules 10 and 20 each of which is excellent in design. Accordingly, by (i) attaching the solar cell module 10 or 20 to a window frame of a building or a vehicle, and using the solar cell module 10 or 20, or (ii) attaching the solar cell module 10 or 20 onto a roof and using the solar cell module 10 or 20, it is possible to realize a highly-efficient solar power generating system.

(Solar Power Generating Device)

A solar power generating device of the present invention includes the aforementioned solar cell module 10 or 20. The solar power generating device of the present invention may include a plurality of solar cell modules 10 or a plurality of solar cell modules 20, and a secondary battery for storing an output received from the plurality of solar cell modules 10 or the plurality of solar cell modules 20. Because the solar power generating device of the present invention includes the solar cell module 10 or 20, the solar power generating device can efficiently convert solar energy into electric power at a location of a window of or a roof of a building, a location of a window of a vehicle, etc.

### Embodiment 2

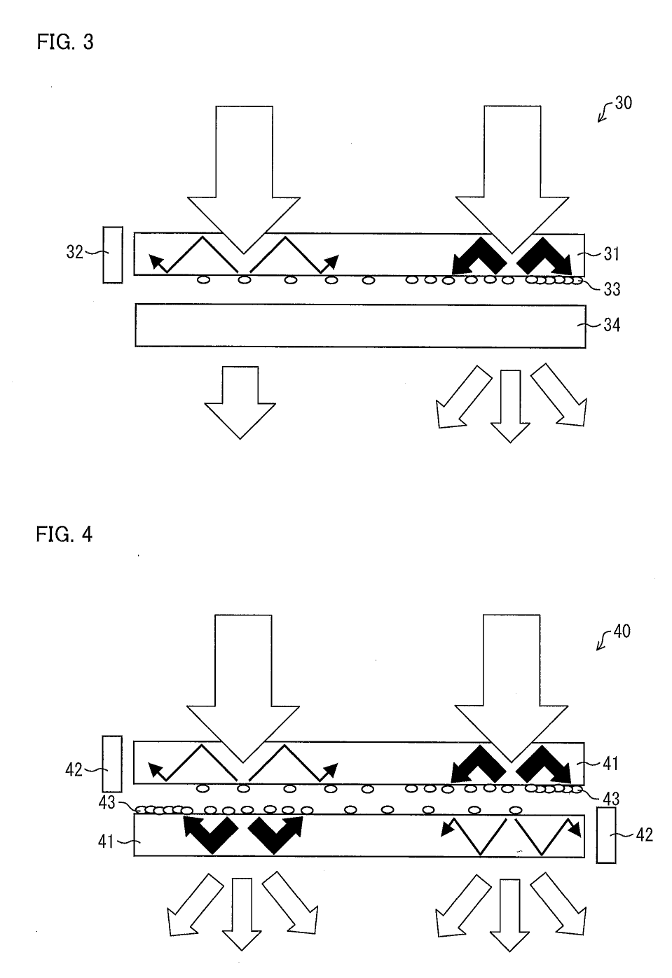

Another embodiment of a solar cell module of the present invention is described below with reference to FIGS. 3 and 4. FIG. 3 is a cross-sectional view illustrating a solar cell module 30, and FIG. 4 is a cross-sectional view illustrating a solar cell module 40. Each of arrows illustrated in FIGS. 3 and 4 indicates a direction in which light is incident or a direction in which light is guided.

As illustrated in FIG. 3, the solar cell module 30 includes a light diffusion section 33 on one (back surface) of surfaces of the light guide plate 31, which one of surfaces is opposite to a light-incident surface of a light guide plate 31. Further, the solar cell module 30 includes a translucent substrate 34. The translucent substrate 34 and the light guide plate 31 are laminated with each other so that the translucent substrate 34 and the back surface face each other. In these points, the solar cell module 30 is different from the solar cell modules 10 and 20 of Embodiment 1. Further, as illustrated in FIG. 4, the solar cell module 40 includes two light guide plates 41, each of which is provided with a light diffusion section 43. The two light guide plates 41 are arranged so that a surface of one of the two light guide plates 41, which surface is provided with one of the two light diffusion sections 43 and is opposite to a light-incident surface of the one of the two light guide plates, faces a surface of the other one of the two light guide plates, which surface is provided with the other one of the two light diffusion sections 43. In these points, the solar cell module 40 is different from the solar cell module 10 or 20 of Embodiment 1. In the present embodiment, only differences between the solar cell modules 30 and 40 and the solar cell modules 10 and 20 are described and other details are omitted here.

The solar cell module 30 includes the light diffusion section 33 on only the back surface of the light guide plate 31, in the same manner as the solar cell module 10. Further, the solar cell module 30 includes the translucent substrate 34. The translucent substrate 34 and the light guide plate 31 are laminated with each other so that the translucent substrate 34 and the back surface face each other. The translucent substrate 34 transmits light that is incident on the translucent substrate 34 from a light guide plate 31 side. The translucent substrate 34 is a plate made from the same material as that of the light guide plate 31. One of surfaces of the translucent substrate 34, which one of surfaces faces the back surface of the light guide plate 31, is a flat surface, and the other one of surfaces of the translucent substrate 34, opposite to the one of surfaces, is also a flat surface. According to the solar cell module 30, the light guide plate 31 and the translucent substrate 34 can be laminated with each other by a method of attaching the light guide plate 31 and the translucent substrate 34 to each other via a translucent adhesive or the like.

As described above, the solar cell module 30 has an arrangement in which one of surfaces of the light guide plate 31, on which the light diffusion section 33 is provided, is covered with the translucent substrate 34. With the arrangement, the light diffusion section 33 is protected by the translucent substrate 34. It is therefore possible to (i) prevent the light diffusion section 33 from being damaged due to contact between the light diffusion section 33 and an object, and (ii) prevent concavities and convexities of the light diffusion section 33 from being filled with dirt. Accordingly, it is possible to prevent a reduction in efficiency of gathering light to the solar cell element 32. Further, the solar cell module 30 can be constituted as multiple glass. Accordingly, it is possible to (i) realize a high-efficient solar power generating system, and also (ii) employ the solar cell module 30 as a windowpane which is excellent in thermal insulating property, for example. Furthermore, it is possible to have an increase in strength of the solar cell module 30 used as a windowpane.

The solar cell module 40 includes the two light guide plates 41 and two solar cell elements 42 which are provided in corresponding positions of the two light guide plates 41, respectively. The two light guide plates 41 are arranged adjacently, and are laminated with each other so that one of surfaces of one of the two light guide plates 41, on which one of the two light diffusion sections 43 is provided, and one of surfaces of the other one of the two light guide plates 41, on which the other one of the two light diffusion sections 43 is provided, face each other. According to the solar cell module 40, the two light guide plates 41 can be laminated with each other by a method of attaching the two light guide plates 41 to each other via a translucent adhesive, or the like.

As described above, the solar cell module 40 has an arrangement in which the two light guide plates 41 are adjacently provided, and one of surfaces of one of the two light guide plates 41, on which one of the two light diffusion sections 43 is provided, is covered with the other one of the two light guide plates 41. With the arrangement, the light diffusion section 43 provided on one of the two light guide plates 41 is protected by the other one of the two light guide plates 41. It is therefore possible to (i) prevent each of the two light diffusion sections 43 from being damaged due to contact between the light diffusion section 43 and an object, and (ii) prevent concavities and convexities of the light diffusion section 43 from being filled with dirt. Accordingly, it is possible to prevent a reduction in efficiency of gathering light to the solar cell elements 42. Further, because the solar cell module 40 can be constituted as multiple glass, it is possible to (i) realize a high-efficient solar power generating system, and also (ii) employ the solar cell module 40 as a windowpane which is excellent in thermal insulating property. Furthermore, it is possible to have an increase in strength of the solar cell module 40 used as a windowpane.

In the present embodiment, the solar cell module 40 includes two light guide plates 41. Note, however, that this is merely an example, and the number of the light guide plates 41 is not limited to 2. In a case where the solar cell module 40 includes a plurality of light guide plates 41, the plurality of light guide plates 41 are arranged such that one of surfaces (back surface) of each of the plurality of light guide plates 41, which surface is provided with a light diffusion section 43, faces an adjacent one of the plurality of light guide plates 41. This prevents the back surface of each of the plurality of light guide plates 41, on which the light diffusion section 43 is provided, from being exposed. Accordingly, it is possible to (i) prevent the light diffusion section 43 from being damaged due to contact between the light diffusion section 43 and an object, and (ii) prevent concavities and convexities of the light diffusion section 43 from being filled with dirt. It is therefore possible to prevent a reduction in efficiency of gathering light to the solar cell element 42.

Moreover, the two light guide plates 41 can be laminated so that the two solar cell elements 42 of the two light guide plates 41 are provided in corners opposite to each other, respectively (see FIG. 4). This causes a region of one of the two light guide plates 41, in which region a large number of concavities and convexities are provided, and a region of the other one of the two light guide plates 41, in which region a large number of concavities and convexities are provided, not to face each other. Accordingly, it is possible to provide multiple glass whose entire surface serves as ground glass.

Here, a solar cell module 30 illustrated in FIG. 3 was manufactured and power generating efficiency of the solar cell module 30 was found. First, a glass substrate (1 m×1 m) having a thickness of 2 mm was prepared. Silicon oxide was sprayed to one of surfaces of the glass substrate by a spraying method, so as to form a convex-concave film whose main component was silicon oxide. A solar cell element 32 including a light receiving section having a width of 10 mm was provided on one of four end surfaces of the glass substrate. Concavities and convexities of the convex-concave film were provided in a gradation manner so that the number of concavities and convexities on upper and lower surfaces of the glass substrate (i) was significantly small in a position close to the one of four end surfaces, on which the solar cell element 32 was provided, and (ii) was large in a position away from the solar cell element 32. Further, a PET sheet on which Ag was vapor-deposited was provided on each of the other three end surfaces, on which no solar cell element 32 was provided, so as to prevent leakage of light from the other three end surfaces. Further, a transparent glass plate was provided to face the one of surfaces of the glass substrate, on which the convex-concave film was provided. A distance between the transparent glass substrate and the one of surfaces of the glass substrate was 10 mm. Double glass was thus manufactured. An amount of electricity generated by the solar cell module 30 thus manufactured was measured, while the solar cell module 30 was irradiated with sunlight. The amount of electricity thus measured was approximately 900 mW.

### Embodiment 3

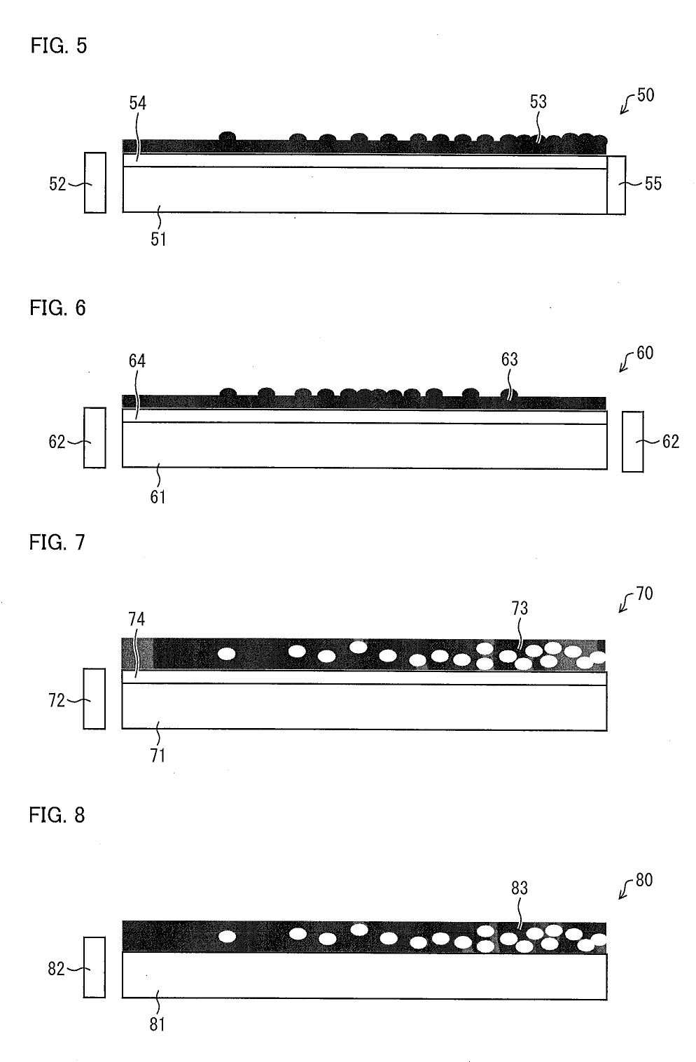

Another embodiment of a solar cell module of the present invention is described below with reference to FIGS. 5 and 6. FIG. 5 is a cross-sectional view illustrating a solar cell module 50, and FIG. 6 is a cross-sectional view illustrating a solar cell module 60. As illustrated in FIG. 5, the solar cell module 50 has an arrangement in which (i) a light diffusion section 53 is provided on a surface of a translucent film (light diffusion layer) 54 and (ii) a solar cell element 52 is provided on one of four end surfaces of a light guide plate 51, and three reflection sections 55 for reflecting light are provided, respectively, on the other three end surfaces of the light guide plate 51, on which no solar cell element 52 is provided. In these points, the solar cell module 50 is different from a solar cell module 10 or 20 of Embodiment 1. Further, as illustrated in FIG. 6, a solar cell module 60 has an arrangement in which (i) a light diffusion section 63 is provided on a surface of a translucent film 64 and (ii) two solar cell elements 62 are provided on two end surfaces opposite to each other, respectively, among four end surfaces of a light guide plate 61. In these points, the solar cell module 60 is different from the solar cell modules 10 and 20 of Embodiment 1. In the present embodiment, only differences between the solar cell modules 50 and 60 and the solar cell modules 10 and 20 are described and other details are omitted here.

The solar cell module 50 has an arrangement in which the translucent film 54 on which the light diffusion section 53 is provided is provided on one of surfaces of the light guide plate 51. The light diffusion section 53 is constituted by concavities and convexities formed by a plurality of light diffusing members which are provided to project from the surface of the translucent film 54. The plurality of light diffusing members are provided on the translucent film 54 so that the number of light diffusing members becomes larger from a position on a solar cell element 52 side toward a position away from the solar cell element 52. Accordingly, it is possible to (i) diffuse light incident on the light guide plate 51 to guide the light efficiently, and, as a result, (ii) gather the light to the solar cell element 52 efficiently. It is therefore possible to enhance efficiency of gathering light to the solar cell element 52.

Further, the solar cell module 50 can be manufactured by attaching, to the light guide plate 51, the translucent film 54 on which the light diffusion section 53 is provided. For this reason, it is unnecessary to form the light diffusion section 53 simultaneously with formation of the light guide plate 51. It is possible to form the light diffusion section 53 by attaching the translucent film 54 to the light guide plate 51 after the formation of the light guide plate 51. Accordingly, the solar cell module 50 can be also manufactured by attaching such a translucent film 54 to an existing windowpane, for example.

Further, the solar cell module 50 includes the three reflection sections 55 for reflecting light on the respective three end surfaces on which no solar cell element 52 is provided, among the four end surfaces of the light guide plate 51. By providing the three reflection sections 55 on the respective three end surfaces on which no solar cell element 52 is provided, it is possible to prevent leakage of light from the three end surfaces. It is thus possible to further improve efficiency of gathering light to the solar cell element 52. Each of the three reflection sections 55 only has to be able to reflect light traveling to an outside via a corresponding one of the three end surfaces of the light guide plate 51, and can be formed by attaching a publicly-known conventional reflection sheet or the like, to the corresponding one of the three end surfaces of the light guide plate 51. Examples of such a reflection section 55 encompass a PET sheet on which Al, Ag, or the like is vapor-deposited and such a sheet that layers made from a dielectric material are laminated with each other.

The translucent film 54 only has to be a film that can transmit light incident on the film. Preferable examples of the translucent film 54 encompass a triacetyl cellulose (TAC) film, a PET film, and an acrylic film. A method of forming the plurality of light diffusing members to project from the surface of the translucent film 54 is not particularly limited. Examples of such a method encompass a method of coating the surface of the translucent film 54 with a resin containing a plurality of light diffusing members, and a method of forming the translucent film 54 with the use of a material containing a plurality of light diffusing members. The resin to which a plurality of light diffusing members are to be mixed may be an ultraviolet cure acrylic resin, for example. Examples of the plurality of light diffusing members provided on the surface of the translucent film 54 encompass silicon oxide beads, titanium oxide beads, and alumina beads.

The solar cell module 60 has an arrangement in which the translucent film 64 on which the light diffusion section 63 is provided is provided on one of surfaces of the light guide plate 61. Further, the light diffusion section 63 is constituted by concavities and convexities formed by a plurality of light diffusing members that are provided to project from a surface of the translucent film 64. In the solar cell module 60, two solar cell elements 62 are provided on two end surfaces opposite to each other, among four end surfaces of the light guide plate 61. Accordingly, the concavities and convexities of the light diffusion section 63 are mainly provided in a center part of the light guide plate 61, which center part is a farthest position from both the two solar cell elements 62. With the arrangement, it is possible to (i) diffuse light incident on the light guide plate 61 to guide the light efficiently, and (ii) gather the light to the solar cell elements 62 efficiently. Accordingly, it is possible to enhance efficiency of gathering light to the solar cell elements 62.

Here, solar cell modules 50 and 60 illustrated in FIGS. 5 and 6, respectively, were manufactured and power generating efficiency of each of the solar cell modules 50 and 60 was found. First, a TAC film was coated with an ultraviolet cure acrylic resin in which silicon oxide beads were mixed, so as to form a convex-concave layer on the TAC film. The TAC film thus formed was attached to an acrylic substrate (1 m×1 m) having a thickness of 2 mm by use of an adhesive. A solar cell element 52 was provided on one of four end surfaces of the acrylic substrate. By controlling an amount of the silicon oxide beads to be mixed in the acrylic resin, concavities and convexities of the convex-concave layer were provided on the one of surfaces of the acrylic substrate in a gradation manner so that the number of concavities and convexities (i) was significantly small in a position close to the one of four end surfaces, on which the solar cell element 52 was provided, and (ii) was large in a position away from the solar cell element 52. Further, three reflection plates were provided, respectively, on the other three end surfaces, on which no solar cell element 52 was provided, so as to prevent leakage of light from the other three end surfaces. An amount of electricity generated by the solar cell module 50 thus manufactured was measured, while the solar cell module 50 was irradiated with sunlight. The amount of electricity thus measured was the same as that of each of the solar cell modules manufactured in the aforementioned Embodiments. Further, another TAC film on which concavities and convexities were formed mainly in a center part of the light guide plate 61 was manufactured, and another solar cell module 60 was manufactured by use of the TAC film. An amount of electricity generated by the another solar cell module 60 thus manufactured was measured, while the another solar cell module 60 was irradiated with sunlight. The amount of electricity thus measured was the same as that of each of the solar cell modules manufactured in the aforementioned Embodiments.

### Embodiment 4

Another embodiment of a solar cell module of the present invention is described below with reference to FIGS. 7 and 8. FIG. 7 is a cross-sectional view illustrating a solar cell module 70, and FIG. 8 is a cross-sectional view illustrating a solar cell module 80. As illustrated in FIG. 7, the solar cell module 70 has an arrangement in which (i) a light diffusion section 73 is provided on a surface of a translucent film 74 and (ii) the light diffusion section 73 is constituted by a resin layer which contains a plurality of light diffusing members having an refractive index that is different from that of a material constituting the resin layer (light diffusing layer). In these points, the solar cell module 70 is different from the solar cell modules 10 and 20 of Embodiment 1. Further, as illustrated in FIG. 8, a solar cell module 80 has an arrangement in which a light diffusion section 83 is constituted by a resin layer which contains a plurality of light diffusing members having a refractive index that is different from that of a material constituting the resin layer. In this point, the solar cell module 80 is different from the solar cell modules 10 and 20. In the present embodiment, only differences between the solar cell modules 70 and 80 and the solar cell modules 10 and 20 are described, and other details are omitted here.

The solar cell module 70 has an arrangement in which the translucent film 74 on which the light diffusion section 73 is provided is provided on one of surfaces of a light guide plate 71. The light diffusion section 73 is constituted by a resin layer containing a plurality of light diffusing members. A refractive index of the plurality of light diffusing members is different from that of a material constituting the resin layer. The light diffusion section 73 contains the plurality of light diffusing members so that the farther away from a solar cell element 72 a position in the light diffusion section 73 is, the larger the number of light diffusing members in the position is.

With the arrangement, light entering the plurality of light diffusing members, among light incident on the resin layer, is diffused because of a difference between a refractive index of the resin layer and a refractive index of the plurality of light diffusing members. The light diffused by the plurality of light diffusing members is guided in the light guide plate 71 and is gathered to the solar cell element 72. Since the number of the plurality of light diffusing members is larger in a position away from the solar cell element 72 than in a position close to the solar cell element 72, it is possible to (i) diffuse the light incident on the light guide plate 71 to guide the light efficiently, and, as a result, (ii) gather the light to the solar cell element 72 efficiently. It is therefore possible to enhance efficiency of gathering light to the solar cell element 72.

Further, it is possible to manufacture the solar cell module 70 by attaching, to the light guide plate 71, the translucent film 74 on which the light diffusing section 73 is provided. Accordingly, it is unnecessary to form the light diffusion section 73 simultaneously with formation of the light guide plate 71. It is possible to form the light diffusion section 73 by attaching the translucent film 74 to the light guide plate 71 after formation of the light guide plate 71. Therefore, it is possible to manufacture the solar cell module 70 by attaching such a translucent film 74 to an existing windowpane, for example.

As long as the resin layer (i) is constituted by the material having the refractive index different from that of the plurality of light diffusing members and (ii) can transmit light, the resin layer is not particularly limited. A layer made from an acrylic resin can be suitably used as the resin layer, for example. The plurality of light diffusing members contained in the resin layer only has to have a refractive index different from that of the resin layer. Examples of the plurality of light diffusing members encompass titanium oxide beads, and alumina beads. A method of forming, on the translucent film 74, the resin layer containing the plurality of light diffusing members is not particularly limited, and may be a method of forming a resin layer by applying, onto the translucent film 74, a material of resin layer which material containing a plurality of light diffusing members and curing the material, for example.

Further, it is possible to have an arrangement of the solar cell module 80 illustrated in FIG. 8. That is, the light diffusion section 83 constituted by the resin layer including the plurality of light diffusing members is directly attached to one of surfaces of a light guide plate 81. Such a solar cell module 80 can be manufactured in such a manner that a material of the resin layer, containing the plurality of light diffusing members, is directly applied to the light guide plate 81, and then is cured to form the resin layer.

Here, solar cell modules 70 and 80 illustrated in FIGS. 7 and 8, respectively, were manufactured, and power generating efficiency of each of the solar cell modules 70 and 80 was found. First, such a polymer that, into an acrylic resin material (refractive index: 1.50), titanium oxide beads (refractive index: 2.50) having an refractive index different from that of the acrylic resin material were mixed, was directly applied to a PET film and then was cured. A resin layer was thus formed. The PET film on which the resin layer was formed was attached to, via an adhesive, an acrylic substrate (1 m×1 m) having a thickness of 2 mm. A solar cell element 72 was provided on one of four end surfaces of the acrylic substrate. By controlling an amount of titanium oxide beads mixed in the acrylic resin material, concavities and convexities were provided in a gradation manner on the one of surfaces of the acrylic substrate so that the number of concavities and convexities (i) was significantly small in a position close to the one of four end surfaces, on which the solar cell element 72 was provided, and (ii) was large in a position away from the solar cell element 72. Further, three reflection plates were provided, respectively, on the other three end surfaces, on which no solar cell element 72 was provided, so as to prevent leakage of light from the other three end surfaces. An amount of electricity generated by the solar cell module 70 thus manufactured was measured, while the solar cell module 70 was irradiated with sunlight. The amount of electricity thus measured was the same as that of each of the solar cell modules manufactured in the aforementioned Embodiments.

Furthermore, such a polymer that, into an acrylic resin material (refractive index: 1.50), titanium oxide beads (refractive index 2.50) having an refractive index different from that of the acrylic resin material were mixed, was directly applied to a glass plate (1 m×1 m) having a thickness of 3 mm, and then was cured. A resin layer was thus formed. A solar cell element 82 was provided on one of four end surfaces of the glass plate. By controlling an amount of titanium oxide beads mixed in the acrylic resin material, concavities and convexities were provided on the one of surfaces of the glass substrate in a gradation manner so that the number of concavities and convexities (i) was significantly small in a position close to the one of four end surfaces, on which the solar cell element 82 was provided, and (ii) was large in a position away from the solar cell element 82. Three reflection plates were provided, respectively, on the other three end surfaces, on which no solar cell element 82 was provided, so as to prevent leakage of light from the other three end surfaces. An amount of electricity generated by the solar cell module 80 thus manufactured was found, while the solar cell module 80 was irradiated with sunlight. The amount of electricity thus measured was the same as that of each of the solar cell modules manufactured in the aforementioned Embodiments.

### Embodiment 5

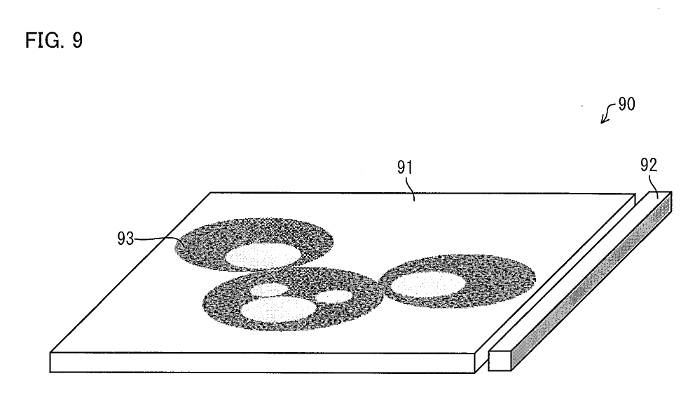

Another embodiment of a solar cell module of the present invention is described below with reference to FIG. 9. FIG. 9 is a perspective view illustrating a solar cell module 90. As illustrated in FIG. 9, the solar cell module 90 has an arrangement in which a light diffusion section 93 is provided on a light guide plate 91 so as to form a pattern on the light guide plate 91. In this point, the solar cell module 90 is different from the solar cell modules 10 and 20 of Embodiment 1. In the present embodiment, only differences between the solar cell module 90 and the solar cell modules 10 and 20 are described and other details are omitted here.

The solar cell module 90 has an arrangement in which the light diffusion section 93 is provided on the light guide plate 91 so as to constitute such a pattern that a plurality of circular shapes are combined with each other. According to the solar cell module 90 having such an arrangement, it is possible to provide the light diffusion section 93 to form a desired pattern. It is therefore possible to have an improvement in design of the solar cell module 90 in a case where the solar cell module 90 is used as a windowpane, for example.

Here, a solar cell module 90 illustrated in FIG. 9 was manufactured and the power generating efficiency of the solar cell module 90 was found. First, a TAC film was coated with an ultraviolet cure acrylic resin in which silicon oxide beads were mixed, so as to form a concave and convex layer on the TAC film. The TAC film thus formed was attached to an acrylic substrate (1 m×1 m) having a thickness of 2 mm via an adhesive, so that a certain pattern was formed on the acrylic substrate. A solar cell element 52 was provided on one of four end surfaces of the acrylic substrate. By controlling an amount of the silicon oxide beads mixed in the acrylic resin, concavities and convexities were provided on a surface of the acrylic substrate in a gradation manner so that the number of concavities and convexities was (i) significantly small in a position close to the one of four end surfaces, on which the solar cell element 92 was provided, and (ii) was large in a position away from the solar cell element 92. Further, three reflection plates were provided, respectively, on the other three end surfaces, on which no solar cell element 92 was provided, so as to prevent leakage of light from the other three end surfaces. An amount of electricity generated by the solar cell module 90 thus manufactured was measured, while the solar cell module 90 was irradiated with sunlight. The amount of electricity thus measured was the same as that of each of the solar cell modules manufactured in the aforementioned Embodiments.

The present invention is not limited to the description of the embodiments above, but may be altered by a skilled person within the scope of the claims. An embodiment based on a proper combination of technical means disclosed in different embodiments is encompassed in the technical scope of the present invention.

Note that the present invention is not limited to the aforementioned Embodiments. A person skilled in the art can modify the present invention within the scope of the claims. In other words, a new embodiment can be obtained by combining technical means appropriately modified, within the scope of the claims. That is, the embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### CONCLUSION OF THE PRESENT INVENTION

In order to attain the object, a solar cell module of the present invention includes: at least one light guide plate; a light diffusion section which is provided on at least one of a light-incident surface of the at least one light guide plate and a back surface of the at least one light guide plate, which back surface is opposite to the light-incident surface, the light diffusion section diffusing light entering the at least one light guide plate; and a solar cell element being provided on one of a plurality of intersecting surfaces that intersect the at least one of the light-incident surface and the back surface, on which the light diffusion section is provided, the light diffusion section being provided so that the farther away from the solar cell element a position is, the larger an amount of light diffused by the light diffusing section in the position is. Further, in order to attain the object, a solar power generating device of the present invention includes the solar cell module described above.

According to the above arrangement, the light diffusion section is provided so that the farther away from the solar cell element a position is, the larger an amount of light diffused by the light diffusing section in the position is. Accordingly, it is possible to (i) diffuse a large amount of light in a position away from the solar cell element, and (ii) suppress diffusion of light in a position close to the solar cell element to reduce loss of light thus guided (light traveling to the outside via upper and lower surfaces). This enhances efficiency of gathering light to the solar cell element. Moreover, the solar cell element is provided on the surface which intersects the light-incident surface of the light guide plate. It is therefore possible to provide a solar cell module which (i) has a small area, (ii) has sufficient power generation efficiency, and (iii) can be manufactured at a low cost. For this reason, the solar cell module can constitute a highly-efficient solar power generating system in such a manner that the solar cell module is attached to a window frame of a building or a vehicle, and used there, or is attached to a roof of a building and used there. In other words, it is possible to provide a solar cell module which has high flexibility in its design and has high light gathering efficiency. Further, a solar power generating device including such a solar cell module can have the same effects of those of the solar cell module.

Further, in the solar cell module of the present invention, it is preferable that the light diffusion section has concavities and convexities so that the farther away from the solar cell element a position is, the larger the number of concavities and convexities in the position is.

According to the arrangement, the light diffusion section having the concavities and convexities is provided on one of surfaces of the light guide plate, so that, among light which enters the light guide plate and is then guided inside the light guide plate, light which is incident on the concavities and convexities inside the light guide plate is (i) diffused by the concavities and convexities, and, as a result, (ii) is returned to the inside of the light guide plate and is guided in the light guide plate. Accordingly, as compared with an arrangement in which the light diffusion section does not have concavities and convexities, it is possible to have an increase in an amount of light guided inside the light guide plate, and therefore have an increase in an amount of light gathered to the solar cell element. It is thus possible to enhance efficiency of gathering light to the solar cell element.

Further, in the solar cell module of the present invention, it is preferable that the concavities and convexities are formed by processing the at least one of the light-incident surface and the back surface of the at least one light guide plate by a sandblasting method. Moreover, in the solar cell module of the present invention, it is preferable that the concavities and convexities are formed by spraying a plurality of light diffusing members to the at least one of the light-incident surface and the back surface of the at least one light guide plate by a spray method. According to the arrangements, the light diffusion section having concavities and convexities can be provided.

Further, in the solar cell module of the present invention, it is preferable that the light diffusion section includes a light diffusing layer, the light diffusing layer including a plurality of light diffusing members so that (i) the plurality of light diffusing members project from a surface of the light diffusing layer, and (ii) the farther away from the solar cell element a position is, the larger the number of light diffusing members in the position is. According to the arrangement, the concavities and convexities of the plurality of light diffusing members are formed on the surface of the light diffusing layer. Accordingly, it is possible to (i) diffuse efficiently light entering the light guide plate by use of the concavities and convexities, and therefore (ii) enhance efficiency of gathering light to the solar cell element efficiently.

Moreover, in the solar cell module of the present invention, it is preferable that the light diffusion section includes a light diffusing layer, the light diffusing layer including a plurality of light diffusing members so that the farther away from the solar cell element a position is, the larger the number of light diffusing members in the position is, and a refractive index of the plurality of light diffusing members and a refractive index of a material constituting the light diffusing layer are different from each other. According to the arrangement, by use of a difference between a refractive index of the plurality of light diffusing members and a refractive index of the light diffusing layer, it is possible to (i) diffuse efficiently light entering the light guide plate, and therefore (ii) enhance efficiency of gathering light to the solar cell element efficiently.

Further, in the solar cell module of the present invention, it is preferable that the light diffusion section is provided only on the back surface of the at least one light guide plate. With the arrangement, it is possible to prevent the light diffusion section from being exposed to the outside by arranging the back surface to face an inside of a room, in a case where the solar cell module is used as a windowpane, for example. This can prevent the light diffusion section from being covered and filled with dirt. As a result, it is possible to prevent a reduction in efficiency of gathering light to the solar cell element.

Furthermore, the solar cell module of the present invention preferably further includes a translucent substrate which is laminated with the at least one light guide plate so as to face the back surface. According to the arrangement, the light diffusion section is not exposed to the outside, so that it is possible to prevent the light diffusion section from being covered and filled with dirt. As a result, it is possible to prevent a reduction in efficiency of gathering light to the solar cell element. Further, the solar cell module can be also used as multiple glass.

Moreover, in the solar cell module of the present invention, it is preferable the at least one light guide plate is a plurality of light guide plates, and the plurality of light guide plates are arranged so that the back surface of each of the plurality of light guide plates is laminated with an adjacent one of the plurality of light guide plates. According to the arrangement, the light diffusion section is not exposed to the outside, so that it is possible to prevent the light diffusion section from being covered and filled with dirt. As a result, it is possible to prevent a reduction in efficiency of gathering light to the solar cell element. Further, the solar cell module can be also used as multiple glass.

Further, in the solar cell module of the present invention, it is preferable that the at least one light guide plate is two light guide plates, and the two light guide plates are arranged so that the back surface of one of the two light guide plates and the back surface of the other one of the two light guide plates face each other. According to the arrangement, the light diffusion section is not exposed to the outside, so that it is possible to prevent the light diffusion section from being covered and filled with dirt. As a result, it is possible to prevent a reduction in efficiency of gathering light to the solar cell element. Further, the solar cell module can be also used as multiple glass.

Furthermore, in the solar cell module of the present invention, it is preferable that reflection sections for reflecting light are provided on the other one(s) of the plurality of intersecting surfaces, on which no solar cell element is provided. According to the arrangement, it is possible to prevent light from being leaked from the other one(s) of the plurality of intersecting surfaces, on which no solar cell element is provided. It is therefore possible to enhance efficiency of gathering light to the solar cell element.

### INDUSTRIAL APPLICABILITY

According to the present invention, it is possible to provide a solar cell module which has high flexibility in design and has high efficiency of gathering light. The solar cell module of the present invention therefore can be suitably used as a solar power generating system provided as a window of a building or a window of a vehicle, or provided on a roof of a building.

### REFERENCE SIGNS LIST

1: Light guide plate
2: Solar cell element
3: Light diffusion section
10: Solar cell module
54: Translucent film (light diffusing layer)

1. A solar cell module comprising:
at least one light guide plate;
a light diffusion section which is provided on at least one of a light-incident surface of the at least one light guide plate and a back surface of the at least one light guide plate, which back surface is opposite to the light-incident surface, the light diffusion section diffusing light entering the at least one light guide plate; and
a solar cell element being provided on one of a plurality of intersecting surfaces that intersect the at least one of the light-incident surface and the back surface, on which the light diffusion section is provided,
the light diffusion section being provided so that the farther away from the solar cell element a position is, the larger an amount of light diffused by the light diffusion section in the position is.

2. The solar cell module as set forth in claim 1, wherein:
the light diffusion section has concavities and convexities so that the farther away from the solar cell element a position is, the larger the number of concavities and convexities in the position is.

3. The solar cell module as set forth in claim 2, wherein:
the concavities and convexities are formed by processing the at least one of the light-incident surface and the back surface of the at least one light guide plate by a sandblasting method.

4. The solar cell module as set forth in claim 2, wherein:
the concavities and convexities are formed by spraying a plurality of light diffusing members to the at least one of the light incident surface and the back surface of the at least one light guide plate by a spray method.

5. The solar cell module as set forth in claim 1, wherein:
the light diffusion section includes a light diffusing layer,
the light diffusing layer including a plurality of light diffusing members so that (i) the plurality of light diffusing members project from a surface of the light diffusing layer, and (ii) the farther away from the solar cell element a position is, the larger the number of light diffusing members in the position is.

6. The solar cell module as set forth in claim 1, wherein:
the light diffusion section includes a light diffusing layer, the light diffusing layer including a plurality of light diffusing members so that the farther away from the solar cell element a position is, the larger the number of light diffusing members in the position is; and
a refractive index of the plurality of light diffusing members and a refractive index of a material constituting the light diffusing layer are different from each other.

7. The solar cell module as set forth in claim 1, wherein:
the light diffusion section is provided only on the back surface of the at least one light guide plate.

8. The solar cell module as set forth in claim 7, further comprising:
a translucent substrate which is laminated with the at least one light guide plate so as to face the back surface.

9. The solar cell module as set forth in claim 7, wherein:
the at least one light guide plate is a plurality of light guide plates; and
the plurality of light guide plates are arranged so that the back surface of each of the plurality of light guide plates is laminated with an adjacent one of the plurality of light guide plates.

10. The solar cell module as set forth in claim 7, wherein:
the at least one light guide plate is two light guide plates; and
the two light guide plates are arranged so that the back surface of one of the two light guide plates and the back surface of the other one of the two light guide plates face each other.

11. The solar cell module as set forth in claim 1, wherein:
reflection sections for reflecting light are provided on the other one(s) of the plurality of intersecting surfaces, on which no solar cell element is provided.

12. A solar power generating device comprising:
a solar cell module recited in claim 1.
